(19) United States
(12) Patent Application Publication
(10) Pub. No.: US 2025/0216100 A1
(43) Pub. Date: Jul. 3, 2025

(54) DUCT STRUCTURE, STOCKER, AND PHOTORESIST BOTTLE MANAGEMENT FACILITIES

(71) Applicant: SEMES CO., LTD., Cheonan-si (KR)

(72) Inventors: Sang Hoon KIM, Incheon (KR); Cheol Yong SHIN, Yongin-si (KR); Jae Youl KIM, Yongin-si (KR); Chun Woo PARK, Yongin-si (KR); Jae Min CHAE, Seoul (KR); Su Hyun KIM, Hwaseong-si (KR)

(21) Appl. No.: 18/944,041

(22) Filed: Nov. 12, 2024

(30) Foreign Application Priority Data
Dec. 27, 2023 (KR) 10-2023-0192506

(51) Int. Cl. F24F 7/08; B65G 1/04; G03F 7/16

(52) U.S. Cl. CPC F24F 7/08; B65G 1/04; G03F 7/162

(57) ABSTRACT

Provided are a duct structure, a stocker, and a photoresist bottle management facility. The duct structure includes an air supply duct disposed on one side of a shelf stack in a stocker and having a plurality of air supply ports formed to correspond to a plurality of layers of the shelf stack and an exhaust duct disposed on the other side of the shelf stack and having a plurality of exhaust ports formed to correspond to the plurality of layers of the shelf stack.

### CROSS-REFERENCE TO RELATED APPLICATION(S)

This application claims benefit of priority to Korean Patent Application No. 10-2023-0192506 filed on Dec. 27, 2023 in the Korean Intellectual Property Office, the disclosure of which is incorporated herein by reference in its entirety.

### BACKGROUND

### 1. Field

The present disclosure relates to a duct structure, a stocker, and a photoresist bottle management facility.

### 2. Description of Related Art

Generally, a photo process for semiconductor manufacturing includes a coating process of applying a photoresist on a substrate to form a photosensitive film, an exposing process of drawing a pattern by irradiating the substrate on which the photosensitive film is formed with light for exposure, and a developing process of developing the exposed substrate to form a pattern.

Among the processes, the coating process of applying the photoresist is mainly performed using a spinner device.

The spinner is configured to rotate the substrate. The photoresist dropped on the center of the substrate is uniformly spread outwardly by the centrifugal force resulting from the rotation of the spinner, thereby coating the substrate.

Meanwhile, the photoresist is stored in a separate photoresist bottle. The photoresist stored in the photoresist bottle may leak from the photoresist bottle, and since there is a risk of explosion due to the leaked gaseous photoresist, the photoresist has to be stored with care.

### RELATED ART DOCUMENT

### Patent Document

(Patent document 1) Korean Application Publication No. 10-2021-0093911

### SUMMARY

An aspect of the present disclosure is to provide a duct structure, a stocker, and a photoresist bottle management facility.

According to an aspect of the present disclosure, a duct structure includes: an air supply duct disposed on one side of a shelf stack in a stocker and having a plurality of air supply ports formed to correspond to a plurality of layers of the shelf stack; and an exhaust duct disposed on the other side of the shelf stack and having a plurality of exhaust ports formed to correspond to the plurality of layers of the shelf stack.

The air supply duct may be vertically disposed to be adjacent to one side of the shelf stack, the exhaust duct may be vertically disposed to be adjacent to the other side of the shelf stack, and each of the plurality of air supply ports and each of the plurality of exhaust ports may have the same height as each of the plurality of layers.

The plurality of air supply ports may have different sizes and may become larger in an air flow direction in the air supply duct.

The plurality of exhaust ports may have different sizes and may become smaller in an air flow direction in the exhaust duct.

A plurality of guide members may be formed to protrude from a lower edge of the plurality of air supply ports toward an inside of the air supply duct.

An upper portion of the air supply duct may be connected to an air supply unit, and the plurality of guide members have different protrusion lengths and protrude further in an air flow direction in the air supply duct.

Each of the plurality of guide members may be formed so that an upper surface thereof is inclined upwardly in a protruding direction.

According to another aspect of the present disclosure, a stocker includes: a shelf stack including a plurality of layers respectively having a storage shelf for a photoresist bottle at a bottom thereof; an air supply duct disposed on one side of the shelf stack and having a plurality of air supply ports formed to correspond to the plurality of layers; and an exhaust duct disposed on the other side of the shelf stack and having a plurality of exhaust ports formed to correspond to the plurality of layers.

According to another aspect of the present disclosure, a photoresist bottle management facility includes: a pair of shelf stacks respectively including a plurality of layers having a storage shelf for a photoresist bottle at a bottom thereof and facing each other; a transport device disposed in a moving space between the pair of shelf stacks, transporting the photoresist bottle disposed on the storage shelf, while moving along the moving space; an air supply duct disposed on one side of the shelf stack and having a plurality of air supply ports corresponding to the plurality of layers; and an exhaust duct disposed on the other side of the shelf stack and having a plurality of exhaust ports corresponding to the plurality of layers.

### BRIEF DESCRIPTION OF DRAWINGS

The and other aspects, features, and advantages of the present disclosure will be more clearly understood from the following detailed description, taken in conjunction with the accompanying drawings, in which:

FIG. 1 is a front view of a stocker according to the related art;

FIG. 2 is a plan view of the stocker of FIG. 1;

FIG. 3 is a side view of the stocker of FIG. 1;

FIG. 4 is a view illustrating flow of air in the stocker of FIG. 3;

FIG. 5 is a perspective view of a stocker according to an embodiment of the present disclosure;

FIG. 6 is a front view of the stocker of FIG. 5;

FIG. 7 is a plan view of the stocker of FIG. 5; and

FIG. 8 is a side view of the stocker of FIG. 5.

### DETAILED DESCRIPTION

Hereinafter, embodiments will be described in detail with reference to the accompanying drawings such that they may be easily practiced by those skilled in the art to which the present disclosure pertains. In describing the present disclosure, if a detailed explanation for a related known function or construction is considered to unnecessarily divert the gist of the present disclosure, such explanation will be omitted but would be understood by those skilled in the art. Also, similar reference numerals are used for the similar parts throughout the specification. In this disclosure, terms., such as “above,” “upper portion,” “upper surface,” “below,” “lower portion,” “lower surface,” “lateral surface,” and the like, are determined based on the drawings, and in actuality, the terms may be changed according to a direction in which a device or an element is disposed.

It will be understood that when an element is referred to as being “connected to” another element, it may be directly connected to the other element or intervening elements may also be present. In contrast, when an element is referred to as being “directly connected to” another element, no intervening elements are present. In addition, unless explicitly described to the contrary, the word “comprise” and variations, such as “comprises” or “comprising,” will be understood to imply the inclusion of stated elements but not the exclusion of any other elements.

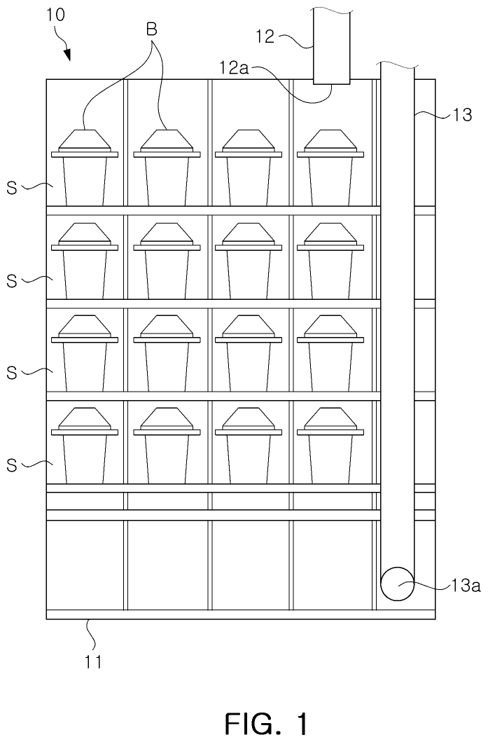

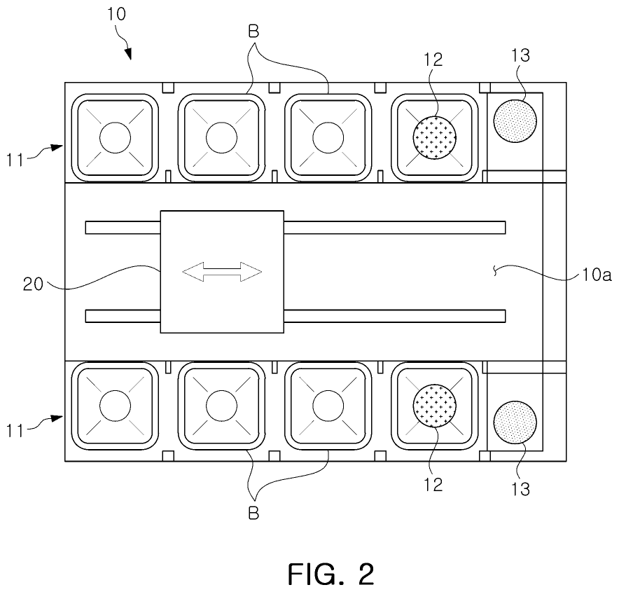

FIG. 1 is a front view of a stocker according to the related art, and FIG. 2 is a plan view of the stocker of FIG. 1.

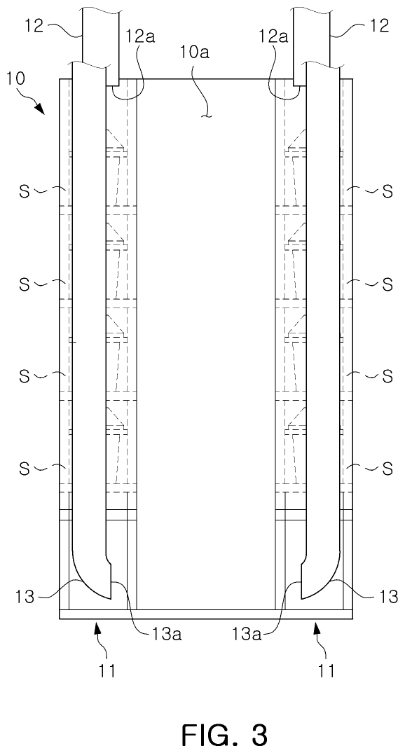

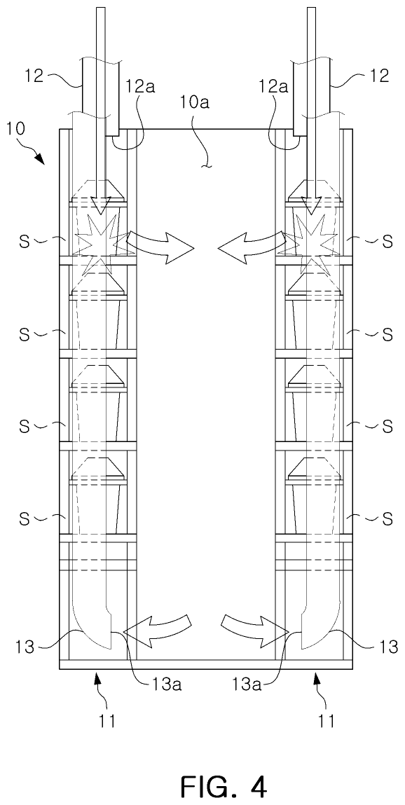

Also, FIG. 3 is a side view of the stocker of FIG. 1, and FIG. 4 is a view illustrating flow of air in the stocker of FIG. 3.

Referring to the drawings, a stocker 10 according to the related art is configured so that air is supplied from the top and air is exhausted from the bottom.

Specifically, the stocker 10 has a shelf stack 11 formed therein, and ab air supply duct 12 is disposed so that an air supply port 12a is located on top of the shelf stack 11, and an exhaust duct 13 is disposed so that an exhaust port 13a is located at the bottom of the shelf stack 11.

Therefore, since the stocker 10 of the related art has a structure in which air is supplied from the top and air is exhausted from the bottom, stagnant air current occurs in a region except for the uppermost end of the shelf stack 11 adjacent to the air supply port 12a.

As an example, as illustrated in the drawing, the stocker 10 has a pair of shelf stacks 11 disposed therein, and a moving space 10a of a transport device 20 is formed between the pair of shelf stacks 11.

In addition, the stocker 10 includes the shelf stack 11 formed of a plurality of layers S.

Here, when air is supplied through the air supply port 12a located at the uppermost layer of the shelf stack 11, the air is blocked by a storage shelf of a photoresist bottle B at the uppermost layer of the shelf stack 11 and does not flow to the immediately lower layer but flows toward the moving space 10a of the transport device 20. As a result, the air supplied through the two air supply ports 12a collides with each other as indicated by the arrows in the drawing.

Due to the air flow direction and collision, the air is difficult to flow back to the shelf stack 11 and flows downwardly through the moving space 10a of the transport device 20 in which no obstacle is present. As a result, air for ventilation hardly reaches the middle and lower layers of the shelf stack 11, and most of the air is exhausted through the exhaust duct 13 disposed on the lower side of the shelf stack 11.

In this manner, in the stocker 10 of the related art, the supplied air is not supplied uniformly to the entirety of the plurality of layers S of the shelf stack 11, so there is a high risk of explosion when a leakage occurs in the photoresist bottle B.

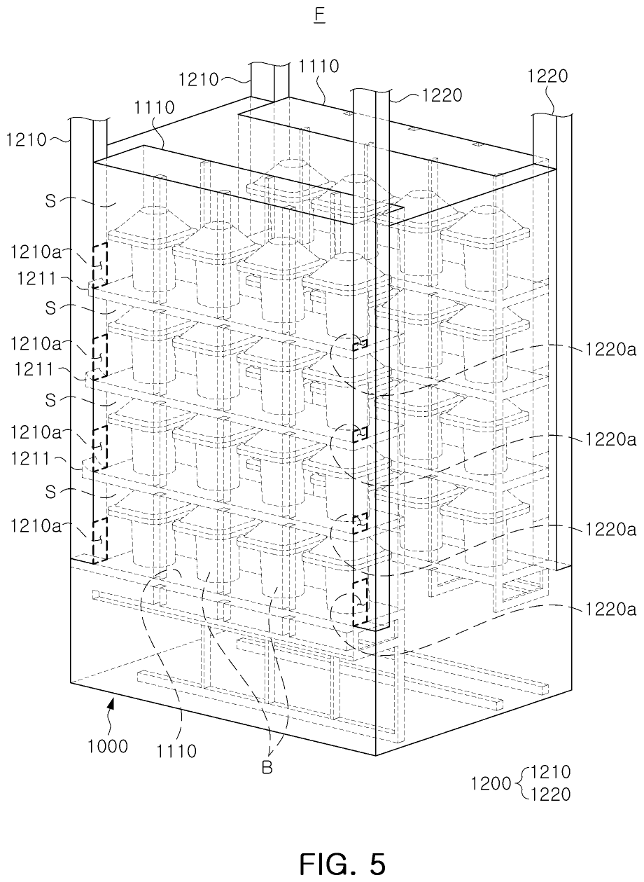

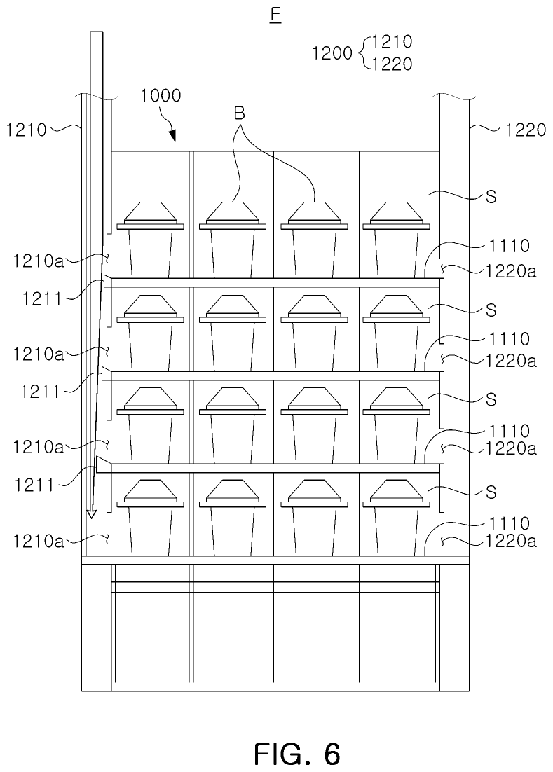

FIG. 5 is a perspective view of a stocker according to an embodiment of the present disclosure, and FIG. 6 is a front view of the stocker of FIG. 5.

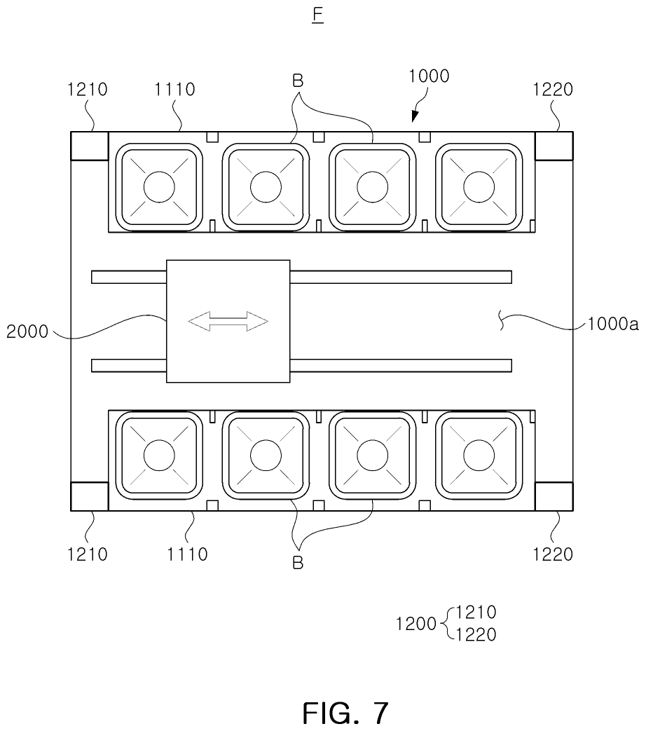

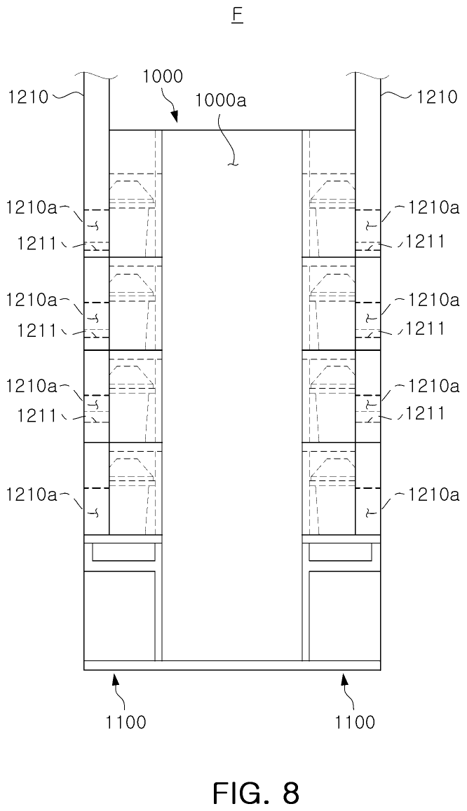

In addition, FIG. 7 is a plan view of the stocker of FIG. 5, and FIG. 8 is a side view of the stocker of FIG. 5.

Referring to the drawings, a photoresist bottle management facility F according to an embodiment of the present disclosure may include a stocker 1000 and a transport device 2000.

Here, the transport device 2000 is a device transporting the photoresist bottle B stored in the stocker 1000.

That is, the transport device 2000 is disposed in a moving space 1000a formed between a pair of shelf stacks 1100 of the stocker 1000 and may transport the photoresist bottle B stacked on the shelf stack 1100, while moving along the moving space 1000a.

The transport device 2000 may be a device that is able to safely and smoothly transport the photoresist bottle B, and a specific structure thereof is not limited by the present disclosure.

In addition, the stocker 1000 may include the shelf stack 1100 and a duct structure 1200.

The shelf stack 1100 may include a plurality of layers S. Each of the plurality of layers S may have a storage region in which the photoresist bottle B is stored. That is, a storage shelf 1110 may be formed at the bottom of each of the plurality of layers S, in which the photoresist bottle B is secured and stored.

The storage shelf 1110 may be formed to elongate from one side of the shelf stack 1100 to the other side thereof so that a plurality of photoresist bottles B are arranged side by side.

The shelf stack 1100 may be formed of the plurality of layers S to safely and easily store the plurality of photoresist bottles B, and without being limited by the present disclosure, the shelf stack 1100 may have any conventional stack structure.

Also, the duct structure 1200 may include an air supply duct 1210 and an exhaust duct 1220.

The air supply duct 1210 may be disposed on one side of the shelf stack 1100. That is, the air supply duct 1210 may be elongate in a longitudinal direction in a space on one side of the shelf stack 1100 to correspond to a longitudinal arrangement structure of the shelf stack 1100. In other words, the air supply duct 1210 may be vertically disposed to be adjacent to one side of the shelf stack 1100.

The air supply duct 1210 may include a plurality of air supply ports 1210a corresponding to the plurality of layers S of the shelf stack 1100. Each of the plurality of air supply ports 1210a may have a structure having the same height as each of the plurality of layers S. Furthermore, the air supply duct 1210 may have a structure in which an upper portion thereof is connected to the air supply unit, thereby forming a flow structure in which air flows downwardly within the air supply duct 1210.

In addition, the exhaust duct 1220 may be disposed on the other side of the shelf stack 1100. That is, the exhaust duct 1220 may elongate in the longitudinal direction in a space on the other side of the shelf stack 1100 to correspond to the longitudinal arrangement structure of the shelf stack 1100. In other words, the exhaust duct 1220 may be vertically disposed to be adjacent to the other side of the shelf stack 1100.

The exhaust duct 1220 may include a plurality of exhaust ports 1220a corresponding to the plurality of layers S of the shelf stack 1100. Each of the plurality of exhaust ports 1220a may have a structure having the same height as each of the plurality of layers S. Furthermore, the exhaust duct 1220 may have a structure in which an upper portion thereof is connected to the air exhaust portion, thereby forming a flow structure in which air flows upwardly within the exhaust duct 1220.

As described above, in the duct structure 1200, the air supply duct 1210 may be disposed on one side of the shelf stack 1100 and the exhaust duct 1220 disposed on the other side of the shelf stack 1100. In addition, a plurality of air supply ports 1210a corresponding to the plurality of layers S of the shelf stack 1100 may be formed in the air supply duct 1210, and a plurality of exhaust ports 1220a corresponding to the plurality of layers S of the shelf stack 1100 may be formed in the exhaust duct 1220.

In the present disclosure, due to the aforementioned configuration of the duct structure 1200, air may be uniformly supplied and discharged with respect to the plurality of layers of the shelf stack 1100, and thus, the entirety of the plurality of layers of the shelf stack 1100 may be uniformly ventilated. Accordingly, since the entirety of the plurality of layers of the shelf stack 1100 may be sufficiently ventilated, the risk of explosion may be eliminated even if a leakage occurs from the photoresist bottle B.

Furthermore, the plurality of air supply ports 1210a may have different sizes.

Specifically, the plurality of air supply ports 1210a may be formed to become larger downwardly in the air flow direction of the air supply duct 1210. In other words, among the plurality of air supply ports 1210a, the air supply port 1210a located relatively higher may be formed smaller and the air supply port 1210a located relatively lower may be formed larger. In other words, the sizes of the air supply ports 1210a may gradually increase in a direction from the uppermost air supply port 1210a to the lowermost air supply port 1210a.

Air flowing in the air supply duct 1210 tends to be supplied with a relatively large amount of air to the air supply port 1210a that air meets first due to air pressure. To prevent this, the sizes of the plurality of air supply ports 1210a may be formed to be different as described above.

That is, since the plurality of air supply ports 1210a are formed with different sizes and become larger in size downwardly in the air flow direction, the air in the air supply duct 1210 may be evenly divided and supplied to the plurality of air supply ports 1210a. As a result, air may be supplied more evenly to the plurality of layers of the shelf stack 1100, and therefore, the entirety of the plurality of layers of the shelf stack 1100 may be ventilated more evenly.

In addition, the plurality of exhaust ports 1220a may be formed to have different sizes.

Specifically, the plurality of exhaust ports 1220a may be formed to become smaller upwardly in the air flow direction of the exhaust duct 1220. That is, among the plurality of exhaust ports 1220a, the exhaust port 1220a located relatively lower may be formed to be larger, and the exhaust port 1220a located relatively upper may be formed smaller. In other words, the sizes of the exhaust ports 1220a may be gradually decrease in a direction from the lowermost exhaust port 1220a to the uppermost exhaust port 1220a.

Air flowing in the air supply duct 1210 tends to be discharged with a relatively large amount of air to the exhaust port 1220a that air meets first after passing through the shelf stack 1100 due to air pressure. To prevent this, as described above, the sizes of the plurality of exhaust ports 1220a may be formed to be different.

In other words, since the plurality of exhaust ports 1220a are formed with different sizes and become smaller in size upwardly in the air flow direction, the air in the air supply duct 1210 may be evenly divided and flow toward the plurality of exhaust ports 1220a. As a result, air may be discharged more evenly from the plurality of layers of the shelf stack 1100, and therefore, the entirety of the plurality of layers of the shelf stack 1100 may be ventilated more evenly.

Meanwhile, the duct structure 1200 of the present disclosure may further include a plurality of guide members 1211.

The plurality of guide members 1211 may be formed to protrude from a lower edge of each of the plurality of air supply ports 1210a toward the inside of the air supply duct 1210. That is, as an example, when the air supply port 1210a is formed on the right side of the air supply duct 1210 as illustrated in FIG. 6, the guide member 1211 may be formed to protrude from the lower edge of the air supply port 1210a to the left, which is an inward direction of the air supply duct 1210.

However, although the guide member 1211 is formed to protrude to the inside of the air supply duct 1210, the guide member 1211 is separated from an internal surface of the air supply duct 1210 located on the opposite side of the air supply port 1210a. Accordingly, a portion of the air flowing in the air supply duct 1210 flows toward the air supply port 1210a, and the remainder continues to flow through the air supply duct 1210 and flows toward the air supply port 1210a located next.

Specifically, the plurality of guide members 1211 may be formed with different protrusion lengths. The plurality of guide members 1211 may protrude further in the air flow direction of the air supply duct 1210. That is, as an example, as illustrated in FIG. 6, an air supply unit may be connected to an upper portion of the air supply duct 1210, in which case, air flows downwardly within the air supply duct 1210. Here, the plurality of guide members 1211 may have a longer protrusion length downwardly, which is the air flow direction of the air supply duct 1210. That is, among the plurality of guide members 1211, the guide member 1211 located relatively lower may protrude further than the guide member 1211 located relatively upper. As for the air flowing in the air supply duct 1210, due to air pressure and linear flow, a relatively small amount of air tends to flow into the air supply port 1210a which the air meets first, and the largest amount of air tends to flow to the air supply port 1210a that the air meets last. To prevent this, as described above, the protrusion lengths of the plurality of guide members 1211 may be different.

That is, the plurality of guide members 1211 are formed to have different protrusion lengths, and the protrusion lengths become longer downwardly in the air flow direction, so that the air flow area of the portion of the air supply duct 1210 in which the guide members 1211 are located is reduced downwardly, so that the air in the air supply duct 1210 may be divided evenly and introduced into the plurality of air supply ports 1210a. As a result, air may be supplied more evenly to the plurality of layers of the shelf stack 1100, and thus the entirety of the plurality of layers of the shelf stack 1100 may be ventilated more evenly.

Furthermore, the plurality of guide members 1211 serve to guide a portion of the air flowing in the air supply duct 1210 to flow smoothly toward the air supply port 1210a.

Specifically, each of the plurality of guide members 1211 may be formed so that an upper surface thereof is inclined upwardly in the protruding direction. That is, as an example, when the air supply port 1210a is formed on the right side of the air supply duct 1210 as illustrated in FIG. 6, the guide member 1211 may have a structure in which the upper surface thereof is inclined upwardly toward the left side, which is in the protruding direction. An air supply unit may be connected to the upper portion of the air supply duct 1210, in which case air flows downwardly within the air supply duct 1210. The air flowing downwardly within the air supply duct 1210 may be guided more smoothly toward the air supply port 1210a by the slope structure formed on the upper surface of the guide member 1211.

As a result, in the present disclosure, since the air supply duct 1210 is disposed on one side of the shelf stack 1100 and the exhaust duct 1220 is disposed on the other side of the shelf stack 1100, air may be supplied and discharged uniformly with respect to the plurality of layers of the shelf stack 1100. Specifically, in the present disclosure, since the plurality of air supply ports 1210a corresponding to the plurality of layers S of the shelf stack 1100 are formed in the air supply duct 1210 and the plurality of exhaust ports 1220a corresponding to the plurality of layers S of the shelf stack 1100 are formed in the exhaust duct 1220, the entirety of the plurality of layers of the shelf stack 1100 may be uniformly ventilated, and thus, the entirety of the plurality of layers of the shelf stack 1100 may be sufficiently ventilated. Accordingly, the present disclosure may eliminate the risk of explosion even if a leakage occurs from the photoresist bottle B.

In the present disclosure, since the air supply duct is disposed on one side of the shelf stack and the exhaust duct is disposed on the other side of the shelf stack, air may be supplied and discharged uniformly with respect to the plurality of layers of the shelf stack. Specifically, in the present disclosure, since the plurality of air supply ports corresponding to the plurality of layers of the shelf stack are formed in the air supply duct and the plurality of exhaust ports corresponding to the plurality of layers of the shelf stack are formed in the exhaust duct, the entirety of the plurality of layers of the shelf stack may be uniformly ventilated, and thus, the entirety of the plurality of layers of the shelf stack may be sufficiently ventilated. Accordingly, the present disclosure may eliminate the risk of explosion even if a leakage occurs from the photoresist bottle.

While embodiments have been illustrated and described above, it will be apparent to those skilled in the art that modifications and variations could be made without departing from the scope of the present disclosure as defined by the appended claims.

What is claimed is:

1. A duct structure comprising:
an air supply duct disposed on one side of a shelf stack in a stocker and having a plurality of air supply ports formed to correspond to a plurality of layers of the shelf stack; and
an exhaust duct disposed on the other side of the shelf stack and having a plurality of exhaust ports formed to correspond to the plurality of layers of the shelf stack.

2. The duct structure of claim 1, wherein
the air supply duct is vertically disposed to be adjacent to one side of the shelf stack,
the exhaust duct is vertically disposed to be adjacent to the other side of the shelf stack, and
each of the plurality of air supply ports and each of the plurality of exhaust ports has the same height as each of the plurality of layers.

3. The duct structure of claim 1, wherein the plurality of air supply ports have different sizes and become larger in an air flow direction in the air supply duct.

4. The duct structure of claim 1, wherein the plurality of exhaust ports have different sizes and become smaller in an air flow direction in the exhaust duct.

5. The duct structure of claim 1, wherein a plurality of guide members are formed to protrude from a lower edge of the plurality of air supply ports toward an inside of the air supply duct.

6. The duct structure of claim 5, wherein an upper portion of the air supply duct is connected to an air supply unit, and the plurality of guide members have different protrusion lengths and protrude further in an air flow direction in the air supply duct.

7. The duct structure of claim 6, wherein each of the plurality of guide members is formed so that an upper surface thereof is inclined upwardly in a protruding direction.

8. A stocker comprising:
a shelf stack including a plurality of layers respectively having a storage shelf for a photoresist bottle at a bottom thereof;
an air supply duct disposed on one side of the shelf stack and having a plurality of air supply ports formed to correspond to the plurality of layers; and
an exhaust duct disposed on the other side of the shelf stack and having a plurality of exhaust ports formed to correspond to the plurality of layers.

9. The stocker of claim 8, wherein
the air supply duct is vertically disposed to be adjacent to one side of the shelf stack, and
the exhaust duct is vertically disposed to be adjacent to the other side of the shelf stack, and
each of the plurality of air supply ports and each of the plurality of exhaust ports has the same height as each of the plurality of layers.

10. The stocker of claim 8, wherein the plurality of air supply ports have different sizes and become larger in an air flow direction in the air supply duct.

11. The stocker of claim 8, wherein the plurality of exhaust ports have different sizes and become smaller in an air flow direction in the exhaust duct.

12. The stocker of claim 8, wherein a plurality of guide members are formed to protrude from a lower edge of the plurality of air supply ports toward an inside of the air supply duct.

13. The stocker of claim 12, wherein an upper portion of the air supply duct is connected to an air supply unit, and the plurality of guide members have different protrusion lengths and protrude further in an air flow direction in the air supply duct.

14. The stocker of claim 13, wherein each of the plurality of guide members is formed so that an upper surface thereof is inclined upwardly in a protruding direction.

15. A photoresist bottle management facility comprising:
a pair of shelf stacks respectively including a plurality of layers having a storage shelf for a photoresist bottle at a bottom thereof and facing each other;
a transport device disposed in a moving space between the pair of shelf stacks, transporting the photoresist bottle disposed on the storage shelf, while moving along the moving space;
an air supply duct disposed on one side of the shelf stack and having a plurality of air supply ports corresponding to the plurality of layers; and
an exhaust duct disposed on the other side of the shelf stack and having a plurality of exhaust ports corresponding to the plurality of layers.

16. The photoresist bottle management facility of claim 15, wherein
the air supply duct is vertically disposed to be adjacent to one side of the shelf stack, and
the exhaust duct is vertically disposed to be adjacent to the other side of the shelf stack, and
each of the plurality of air supply ports and each of the plurality of exhaust ports has the same height as each of the plurality of layers.

17. The photoresist bottle management facility of claim 15, wherein the plurality of air supply ports have different sizes and become larger in an air flow direction in the air supply duct, and the plurality of exhaust ports have different sizes and become smaller in an air flow direction in the exhaust duct.

18. The photoresist bottle management facility of claim 15, wherein a plurality of guide members are formed to protrude from a lower edge of the plurality of air supply ports toward an inside of the air supply duct.

19. The photoresist bottle management facility of claim 18, wherein an upper portion of the air supply duct is connected to an air supply unit, and the plurality of guide members have different protrusion lengths and protrude further in an air flow direction in the air supply duct.

20. The photoresist bottle management facility of claim 19, wherein each of the plurality of guide members is formed so that an upper surface thereof is inclined upwardly in a protruding direction.
